(19) United States
(12) Patent Application Publication
(10) Pub. No.: US 2011/0210411 A1
(43) Pub. Date: Sep. 1, 2011

(54) ULTRA THIN FLIP-CHIP BACKSIDE DEVICE SENSOR PACKAGE

(75) Inventors: Sukhminder S. Binapal, Burlington (CA); David A. Roy, Port Colborne (CA)

(73) Assignee: SOUND DESIGN TECHNOLOGIES, LTD., Burlington (CA)

(21) Appl. No.: 12/763,289

(22) Filed: Apr. 20, 2010

Related U.S. Application Data
(60) Provisional application No. 61/308,720, filed on Feb. 26, 2010.

(51) Int. Cl. H01L 29/82; H01L 21/50

(52) U.S. Cl. 257/427; 438/48; 257/E29.323; 257/E21.499

(57) ABSTRACT

An integrated circuit that senses a phenomenon, such as a magnetic field, may be mounted upside down on a carrier substrate so that the electrical connections to the integrated sensor circuit may be made on the side facing the carrier. This eliminates the need for wirebonds on the side of the sensor integrated circuit that faces the phenomenon being sensed, thereby substantially eliminating any uneven topography on that side. The sensor integrated circuit is able to sense the phenomenon by sensing it through the body of the sensor integrated circuit. The body of the sensor integrated circuit may have a thickness within a vicinity of fifty microns.

### CROSS-REFERENCE TO RELATED APPLICATIONS

This application claims priority to U.S. provisional application Ser. No. 61/308,720 filed Feb. 26, 2010, entitled Ultra Thin Flip-Chip Backside Device Sensor Package, by applicants Binapal et al., the complete disclosure of which is hereby incorporated herein by reference.

### BACKGROUND OF THE INVENTION

The present invention relates to the manufacture of miniaturized sensors, such as micro electrical mechanical systems (MEMS).

In the past, the performance of sensors on integrated circuits, such as, but not limited to, magnetic field sensors, has required the sensing region of the sensors to be in very close physical proximity to the sensed phenomenon. Such prior sensors on integrated circuits have been wire-bonded. The typical wire bonded approach has been to connect a sensor to a carrier and use a glop top to protect the wire bonds. An example of this can be seen in FIG. 5. The wirebonds connect between a top surface of an integrated circuit and a carrier positioned beneath the integrated circuit. In some applications a membrane may cover the top of the integrated circuit and the encapsulated wirebonds. Regardless of the presence or absence of the membrane, the encapsulated wirebonds creates an uneven surface topography on the top side of the integrated sensor circuit that may interfere with the sensing of the phenomenon, and which may cause varying results from sensor to sensor to due differences in the shape of the wire bond and glob top from one sensing unit to another. Such interference and variance in sensing packages may be undesirable. Further, when a membrane is used, the uneven topography of the glop top may create a varying distance between the top of the integrated sensor circuit and the membrane, which may also adversely affect the device performance and the repeatability of the sensor.

### SUMMARY OF THE INVENTION

According to its various aspects, the present invention provides an improved sensor package that overcomes or ameliorates one or more of the disadvantages of the prior art. In at least some embodiments, a sensor integrated circuit is mounted upside down on a carrier substrate so that the electrical connections to the integrated sensor circuit may be made on the side facing the carrier. This eliminates the need for wirebonds on the side of the sensor integrated circuit that faces phenomenon being sensed, thereby substantially eliminating any uneven topography on that side. The sensor integrated circuit is able to sense the phenomenon by sensing it through the body of the sensor integrated circuit.

In one embodiment, a method of manufacturing a sensor package is provided that includes providing a carrier and a sensor integrated circuit. The sensor integrated circuit includes an active side on which a sensing circuit is built up and a non-active side opposite the active side. The sensing circuit is adapted to sense a presence or absence of a phenomenon within a proximity to the sensing circuit. The method further includes attaching the sensor integrated circuit to the carrier such that the active side faces the carrier and the inactive side faces away from the carrier. The method may further include sensing the presence or absence of the phenomenon through the body of the sensor integrated circuit.

According to another embodiment, a sensor package is provided that includes an integrated circuit, a sensor, and a carrier. The integrated circuit includes an active side and an inactive side. The sensor is formed on the active side of the integrated circuit and is adapted to detect a phenomenon. The carrier attaches to the integrated circuit such that the active side of the circuit faces the carrier, whereby the sensor is able to detect the phenomenon when the phenomenon is present on the inactive side of the integrated circuit.

### BRIEF DESCRIPTION OF THE DRAWINGS

FIG. 1 is an elevational, schematic view of a sensor package according to a first embodiment;

FIG. 2 is perspective diagram of a sensor package according to a second embodiment in which a carrier channel is absent;

FIG. 3 is a plan view of the sensor package of FIG. 2;

FIG. 4 is a flowchart of a method by which the sensor packages of the present invention may be manufactured; and

FIG. 5 is a perspective view of a prior art sensor package.

### DETAILED DESCRIPTION OF THE EMBODIMENTS

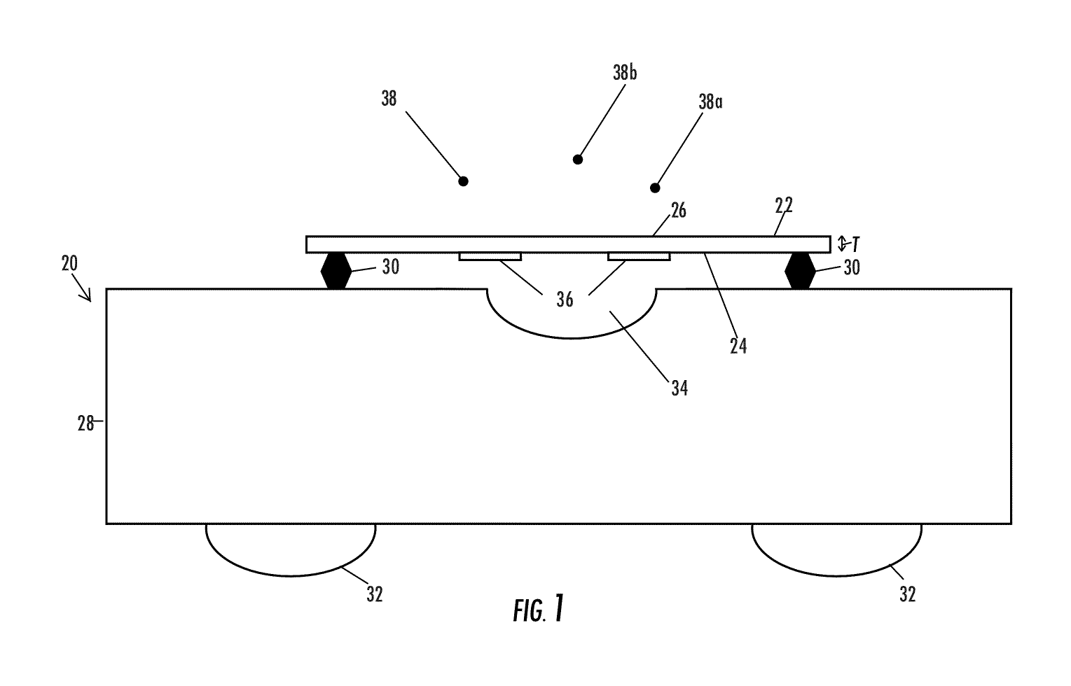

A sensor package 20 according to a first embodiment is shown in FIG. 1. Sensor package 20 includes an integrated circuit 22 having an active side 24 and an inactive side 26. Sensor package 20 further includes a carrier 28 that is electrically coupled to integrated circuit 22 by way of one or more solder joints 30. Carrier 28 may further include one or more solder bumps 32 that enable carrier 28 to be electrically coupled to a printed circuit board (PCB), or other structure. A channel 34 is defined in a top of carrier 28.

Integrated circuit 22 may be a conventional integrated circuit having one or more sensor circuits or sensors 36 incorporated into it. Typically, such integrated circuits are manufactured from silicon, or like material, and are developed by forming or otherwise building up circuit elements on one side of the material. For purposes of description herein, that side of the chip or material will be referred to as the active side. The circuit elements may be built up on the active side in any conventional manner, such as by etching, deposition, patterning, etc. In at least one embodiment, sensors 36 are sensors that detect magnetic fields. In other embodiments, sensors 36 may detect other phenomena, such as, but not limited to, electrical fields. Still other phenomenon may be detected by sensors 36 as well.

In the embodiment illustrated in FIG. 1, sensor package 20 is able to detect a phenomenon, such as a magnetic field, that is positioned within the vicinity of inactive side 26. For example, sensor 36 is able to detect a magnetic field within the vicinity of location 38. Similarly, it may detect a magnetic field in locations 38a, or 38b, or any other regions on the inactive side 26 of integrated circuit 22. This contrasts with the prior art where the active side of a sensor integrated circuit was positioned to face the phenomenon being sensed by the sensor integrated circuit. Thus, sensor package 20 is adapted to sense the phenomenon through the integrated circuit 22. Stated alternatively, the sensor or sensors 36 are able to detect phenomenon positioned on the opposite side of integrated circuit 22 as the sensor or sensors 36.

By attaching integrated circuit 22 to carrier 28 in such a manner so that active side 24 faces carrier 28, solder joints 30 may be placed on active side 24 via a flip chip method. Because solder joints 30 are positioned on active side 24, rather than inactive side 26, this leaves inactive side 26 free of substantial obstructions that would otherwise significantly alter the substantially flat and planar topography of inactive side 26. Further, because inactive side 26 is substantially planar, sensor packages 20 may be made with more repeatable sensing characteristics, and there is no physical structure that interferes with bringing integrated circuit 22 into close proximity with the phenomenon. Further, if desired, a membrane may be placed over inactive side 26, and such membrane will generally lie flat against the planar surface defined by inactive side 26.

In some embodiments, the thickness T of integrated circuit 22 (FIG. 1) may affect the sensing ability of sensors 36. In such embodiments, it may be desirable to make the thickness of integrated circuit 22 relatively small. In some embodiments, integrated circuit 22 may have a thickness of less than seventy-five microns. In other embodiments, integrated circuit 22 may have a thickness of less than fifty microns. Still thinner dimensions may be used in other embodiments.

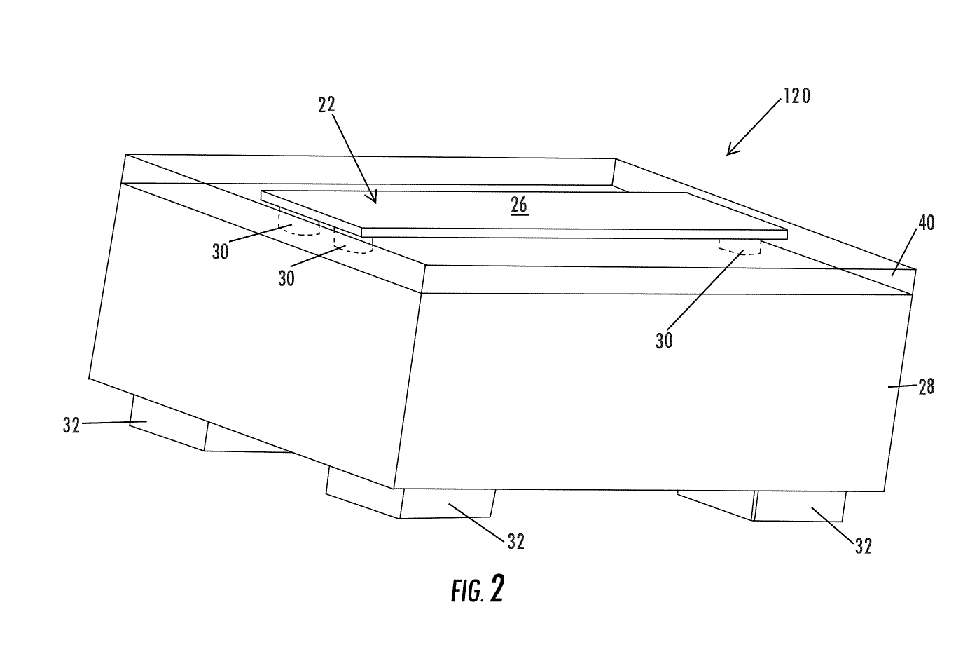

Underfill material 40, such as is shown in sensor package 120 of FIG. 2, may be placed over the top surface of carrier 28 (i.e. the surface that faces integrated circuit 22). Such underfill material may be conventional underfill material used in the semiconductor manufacturing industry, as would be known to one of ordinary skill in the art. While not shown in the embodiment of FIG. 2, carrier 28 may have a channel 34 (FIG. 1) defined in it that allows excess underfill material to be received so that the underfill does not extend higher than the plane defined by inactive side 26 of integrated circuit 22. Stated alternatively, channel 34 helps prevent the underfill material from overflowing onto inactive side 26 of integrated circuit 22, which would otherwise create an uneven surface topography and may interfere with the sensing ability of sensors 36.

The dimensions of channel 34 may vary widely, and the dimensions do not need to be uniform throughout the body of carrier 28. In some embodiments, channel 34 may be any shape that allows the underfill material to escape out one or more sides of carrier 34.

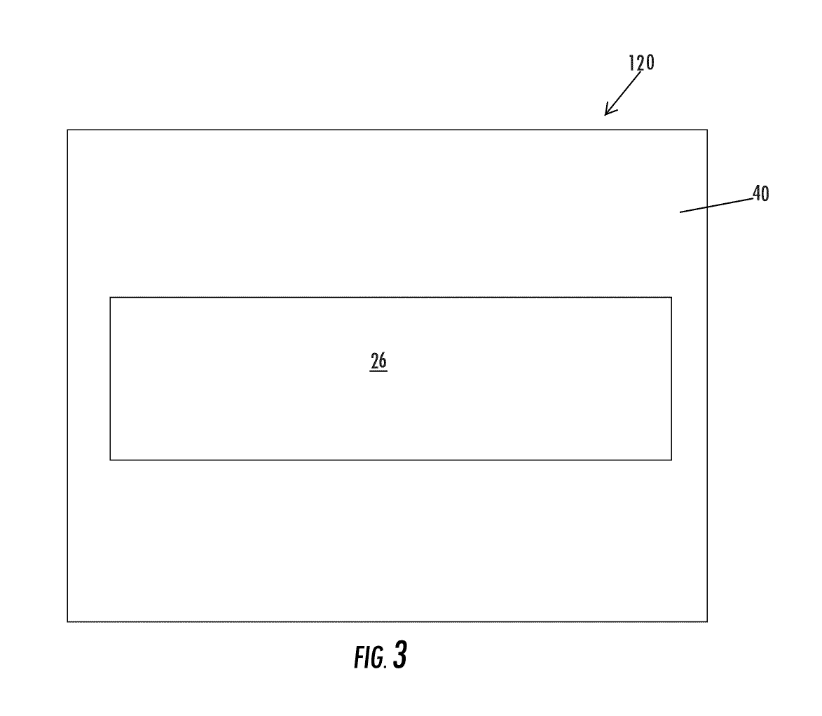

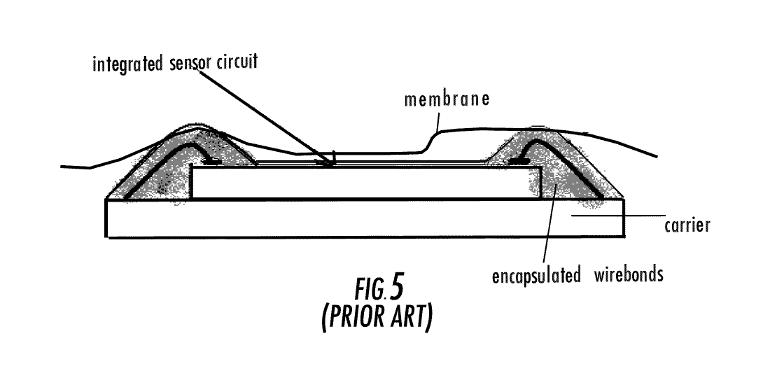

Sensor package 20 may be used as part of a larger device or instrument that senses any desired phenomenon. In at least one embodiment, as noted, sensor package 20 may be adapted to detect magnetic fields. Such an embodiment may be specifically useful as part of a medical diagnostic used for detecting magnetic fields in blood. Such magnetic sensing may be done on unaltered blood, or it may be performed after a patient has ingested, or otherwise received, substances that have specific magnetic properties that are desirably detected by sensor package 20. When used in this application, it may be desirable to position a membrane over the integrated circuit, more specifically, over inactive side 26 of integrated circuit 22. While not shown in FIGS. 1-3, such a membrane may be made of conventional materials and attached in a conventional manner. FIG. 5 illustrates how a membrane may be positioned over a prior art sensor package.

It will, of course, be understood by those skilled in the art that sensor package 20 may be used for other applications besides medical diagnostic testing, and, as noted, may be used to detect phenomenon besides magnetic fields, such as electrical fields, or other phenomenon which are capable of being sensed through the body of integrated circuit 22 by one or more sensors or sensing circuits 36.

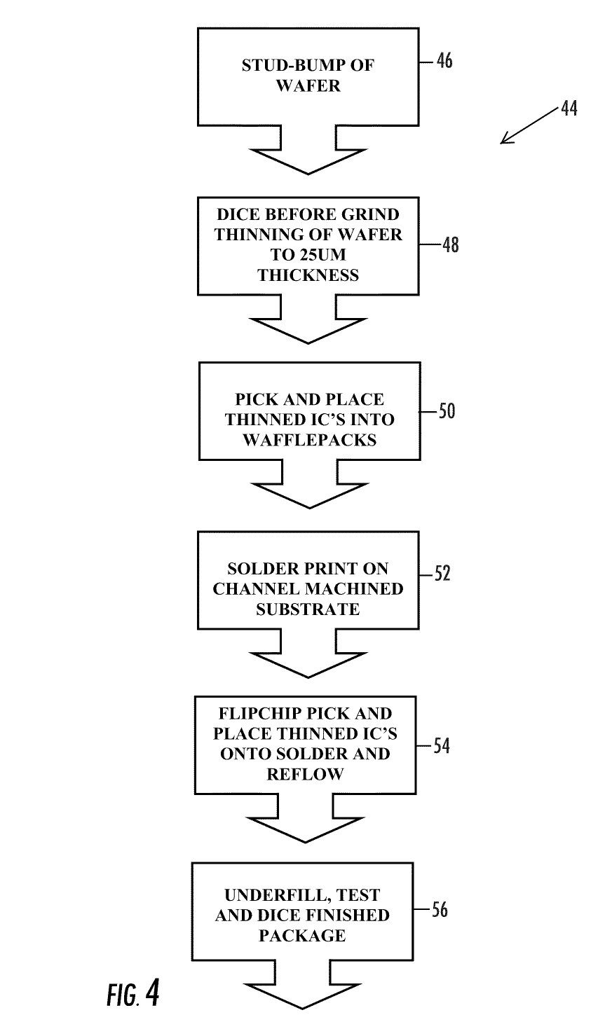

FIG. 4 illustrates a method 44 by which one or more sensor packages 20 may be manufactured. Method 44 begins at a first step 46 in which stud bumps are formed in any known manner on a wafer containing multiple copies of the integrated circuit 22. The wafer may be a silicon wafer, or other material, that is used in manufacturing integrated circuit 22. After the stud bumps are formed in step 46, the wafer is diced at step 48 into as many integrated circuits 22 as there are defined on the wafer. At step 48, the wafers may also be ground down to a lower thickness, depending upon the thickness of the original wafer and the particular sensing undertaken by integrated circuits 22. In at least one embodiment, the diced wafers may be ground down to a thickness of less than fifty micrometers, including a thickness of twenty-five micrometers or less. Such thinning may be accomplished by any known method.

After the completion of step 48, the individual integrated circuits 22 are pick and placed into a wafflepack at step 50. At step 52, solder is printed onto one or more carriers 28, such as the solder that defines solder joints 30. Thereafter, at step 54, the integrated circuits are flip chipped onto the carriers 28 and the solder joints 30 are reflowed to thereby create the electrical connections between carriers 28 and the integrated circuits 22. At step 56, conventional underfill material is added, the sensor packages may be tested, and the multiple carriers 22 and integrated circuits 22 may be diced into individual sensors packages 20. As noted, a membrane may thereafter be added in some embodiments.

It will be understood by those skilled in the art that modifications may be made to the various embodiments described herein, and that the arrangement and manufacture of sensors packages 20 may be applied to other microelectromechanical structures (MEMS).

It will also be understood that, in one embodiment, integrated circuit 22 may be a conventional AA005 Giant Magnetoresistive (GMR) sensor integrated circuit manufactured by NVE Corporation of Eden Prairie, Minn. Other types of sensor integrated circuits 22 may be incorporated into package 20 as well.

While several forms of the invention have been shown and described, other forms will now be apparent to those skilled in the art. It should be understood that the embodiments shown in the drawings and described above are merely for illustrative purposes, and are not intended to limit the scope of the invention which is defined by the claims which follow as interpreted under the principles of patent law including the doctrine of equivalents.

What is claimed is:

1. A method of manufacturing a sensor package comprising:
providing a carrier;
provide a sensor integrated circuit having an active side on which a sensing circuit is built up and a non-active side opposite said active side, said sensing circuit adapted to sense a presence or absence of a phenomenon within a proximity to said sensing circuit;
attaching said sensor integrated circuit to said carrier such that said active side faces said carrier and said inactive side faces away from said carrier;
sensing the presence or absence of said phenomenon through said sensor integrated circuit.

2. The method of claim 1 further including:
reflowing solder positioned between said active side and said carrier in order to electrically connect said sensor integrated circuit to said carrier.

3. The method of claim 1 further including placing a membrane on said inactive side of said sensor integrated circuit.

4. The method of claim 1 further including thinning said sensor integrated circuit to a thickness of not more than fifty microns prior to attaching said sensor integrated circuit to said carrier.

5. The method of claim 1 wherein said sensor integrated circuit is adapted to detect a magnetic field.

6. The method of claim 1 further including forming a channel in said carrier on a side of said carrier that faces said active side of said sensor integrated circuit.

7. The method of claim 6 wherein said carrier channel is adapted to receive any excess underfill material and prevent said underfill material from overflowing onto said inactive side of said sensor integrated circuit.

8. The method of claim 1 further including dicing said sensor integrated circuit from a wafer containing multiple ones of said sensor integrated circuits.

9. The method of any of claim 1 wherein said carrier is made of aluminum oxide.

10. The method of any of claim 1 further including positioning solder on a side of said carrier facing said sensor integrated circuit, said solder adapted to be reflowed to allow an electrical connection to be made between said carrier and said sensor integrated circuit.

11. The method of claim 10 further including positioning at least one solder ball on a side of said carrier opposite said integrated circuit, said solder ball adapted to be reflowed to allow an electrical connection to be made between said carrier and a printed circuit board.

12. A sensor package comprising:
an integrated circuit having an active side and an inactive side;
a sensor formed on said active side of said integrated circuit, said sensor adapted to detect a phenomenon;
a carrier attached to said integrated circuit such that said active side of said circuit faces said carrier, whereby said sensor is able to detect said phenomenon when said phenomenon is present on said inactive side of said integrated circuit.

13. The package of claim 12 wherein solder is positioned between said active side and said carrier in order to electrically couple said sensor circuit to said carrier.

14. The package of claim 12 further including a membrane positioned on said inactive side of said sensor integrated circuit.

15. The package of claim 12 wherein said integrated circuit has a thickness of not more than fifty microns.

16. The package of claim 12 wherein said sensor is adapted to detect a magnetic field.

17. The package of claim 12 wherein said carrier includes a channel formed therein on a side that faces said active side of said integrated circuit said carrier channel adapted to receive any excess underfill material and prevent said underfill material from overflowing onto said inactive side of said integrated circuit.

18. The package of claim 12 wherein said carrier is a ceramic.

19. The package of claim 12 wherein at least one solder ball is positioned on a side of said carrier opposite said integrated circuit, said solder ball adapted to be reflowed to allow an electrical connection to be made between said carrier and a printed circuit board.

20. The package of claim 12 wherein solder is positioned between said active side and said carrier in order to electrically couple said sensor circuit to said carrier;
wherein said integrated circuit has a thickness of not more than fifty microns;
wherein said sensor is adapted to detect a magnetic field;
wherein said carrier is ceramic;
wherein said carrier includes a channel formed therein on a side that faces said active side of said integrated circuit, said carrier channel adapted to receive any excess underfill material and prevent said underfill material from overflowing onto said inactive side of said integrated circuit; and
wherein at least one solder ball is positioned on a side of said carrier opposite said integrated circuit, said solder ball adapted to be reflowed to allow an electrical connection to be made between said carrier and another structure.
